(19) United States
(12) Patent Application Publication
(10) Pub. No.: US 2016/0077555 A1
(43) Pub. Date: Mar. 17, 2016

(54) USB MEMORY DEVICE

(71) Applicant: KABUSHIKI KAISHA TOSHIBA, Minato-ku (JP)

(72) Inventors: Yuuta YAMADA, Yokohama (JP); Takeshi MITSUHASHI, Yokohama (JP); Junichi ASADA, Sagamihara (JP)

(73) Assignee: KABUSHIKI KAISHA TOSHIBA, Minato-ku (JP)

(21) Appl. No.: 14/844,511

(22) Filed: Sep. 3, 2015

(30) Foreign Application Priority Data
Sep. 11, 2014 (JP) 2014-185375

(51) Int. Cl. G06F 1/18; G11C 16/04

(52) U.S. Cl. CPC G06F 1/18; G11C 16/04

(57) ABSTRACT

According to one embodiment, a USB memory device includes: a substrate including a semiconductor chip, a plurality of operating terminals, a reference potential terminal and a reference potential wiring; and a housing holding the substrate inside, being electrically connected to the reference potential terminal, and having electric conductivity. The reference potential wiring electrically connects the operating terminal with the reference potential terminal.

### CROSS-REFERENCE TO RELATED APPLICATIONS

This application is based upon and claims the benefit of priority from Japanese Patent Application No. 2014-185375, filed Sep. 11, 2014, the entire contents of which are incorporated herein by reference.

### FIELD

Embodiments described herein relate generally to a USB memory device.

### BACKGROUND

Recently, Universal Serial Bus (USB) memory devices each including a flash memory and having a USB connector have been known as a detachable storage medium used for electronic devices such as a personal computer (PC).

### BRIEF DESCRIPTION OF THE DRAWINGS

FIGS. 1 to 3 are a perspective view, an exploded view and a cross-sectional view of a USB memory device according to the first embodiment;

FIG. 4 is a cross-sectional view of the connected part between a reference potential terminal and a housing of a USB memory device according to the first example in the second embodiment.

FIG. 5 is a cross-sectional view of the connected part between a reference potential terminal and a housing of the USB memory device according to the second example in the second embodiment.

FIG. 6 is a cross-sectional view of the connected part between a reference potential terminal and a housing of the USB memory device according to the third example in the second embodiment.

FIG. 7 is a cross-sectional view of the connected part between a reference potential terminal and a housing of the USB memory device according to the fourth example in the second embodiment.

FIG. 8 is a cross-sectional view of the connected part between a reference potential terminal and a housing of the USB memory device according to the fourth example in the second embodiment.

FIG. 9 is a perspective view of a substrate of a USB memory device according to the third embodiment.

FIG. 10 is a cross-sectional view of the USB memory device according to the third embodiment.

FIGS. 11 to 13 are a perspective view, an exploded view and a cross-sectional view of a USB memory device according to the first example in the fourth embodiment;

FIGS. 14 and 15 are a perspective view and an exploded view of a USB memory device according to the second example in the fourth embodiment;

FIG. 16 is a perspective view of a housing of a USB memory device according to the fifth embodiment;

FIG. 17 is a cross-sectional view of the USB memory device according to the fifth embodiment;

FIG. 18 is a cross-sectional view of the USB memory device according to the sixth embodiment;

FIGS. 19 and 20 are a perspective view and an exploded view of a substrate and a conductor of a USB memory device according to the seventh embodiment;

FIG. 21 is a cross-sectional view of the USB memory device according to the seventh embodiment; and

FIG. 22 is a cross-sectional view of the USB memory device according to the eighth embodiment.

### DETAILED DESCRIPTION

In general, according to one embodiment, a USB memory device includes: a substrate and a housing. The substrate includes a semiconductor chip capable of storing data, a plurality of operating terminals electrically connectable to an external device, a reference potential terminal, and a reference potential wiring. The housing holds the substrate inside, is electrically connected to the reference potential terminal, and has electric conductivity. One of the operating terminals is applied a reference potential from an external device. The reference potential wiring electrically connects the one of operating terminals with the reference potential terminal.

### 1. First Embodiment

A USB memory device according to the first embodiment will be described.

### 1.1 Configuration of USB Memory Device

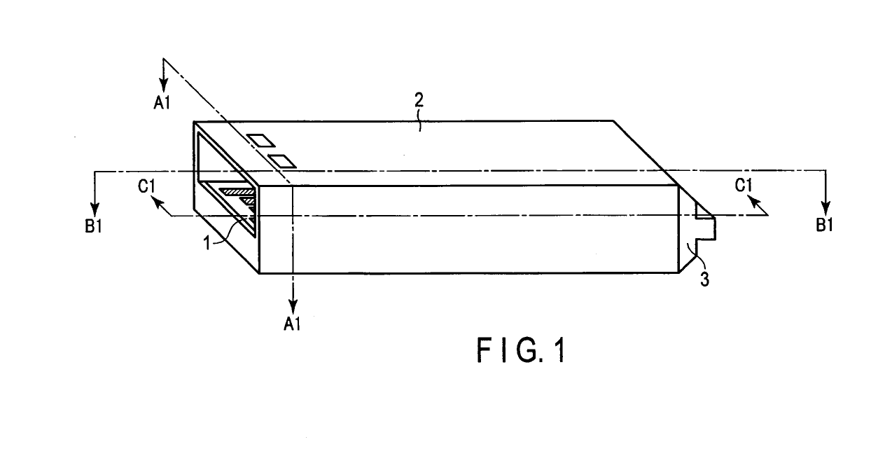

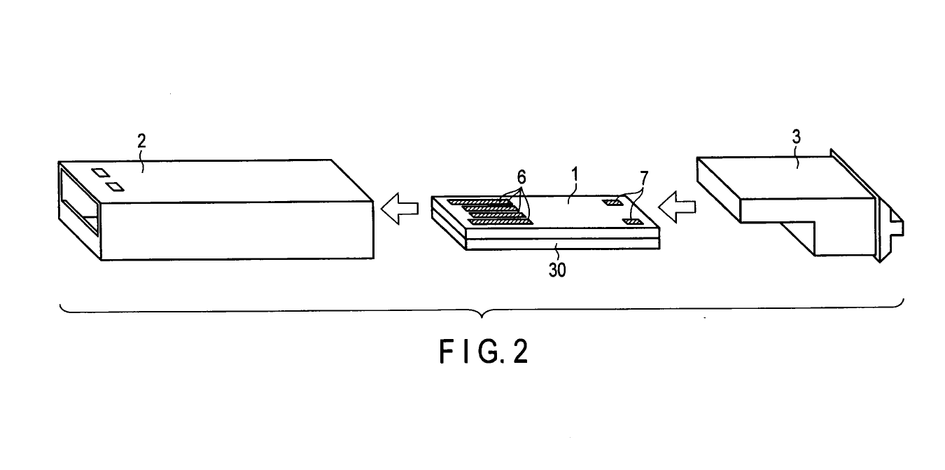

First, the configuration of the USB memory device according to the present embodiment will be explained with reference to FIG. 1 and FIG. 2. FIG. 1 is a perspective view of the USB memory device according to the present embodiment, and FIG. 2 is an exploded view of the USB memory device shown in FIG. 1.

As shown in FIG. 1 and FIG. 2, the USB memory device includes a substrate 1, a housing 2, and a sealing member 3.

The substrate 1 includes four operating terminals 6 on its upper surface, and two reference potential terminals 7. The substrate 1 includes a semiconductor chip and a circuit connected to the semiconductor chip (not shown in the drawings) on its bottom surface. The substrate 1 also includes a sealing resin 30 to protect the semiconductor chip and the circuit.

The semiconductor chip includes a semiconductor memory chip capable of storing data (e.g., NAND flash memory), and a semiconductor control chip for controlling the semiconductor memory chip. The semiconductor memory chip and semiconductor control chip may be formed by one semiconductor chip, or by independent semiconductor chips.

The operating terminals 6 electrically connect a USB memory device with an external device (host device). The four operating terminals 6 include a terminal receiving source voltage from the external device, and a terminal transmitting and receiving a control signal and data. At least one of the operating terminals 6 is a terminal receiving a reference potential (e.g., a ground potential) from the external device. The number of operating terminals 6 is not limited to four, and may be three or less, or five or more.

The reference potential terminals 7 are connected to the housing 2. The reference potential terminals 7 are connected to a terminal receiving a reference potential among the operating terminals 6 by the reference potential wiring (not shown in the drawings) provided on the substrate 1. The number of operating terminals 7 is not limited to two, and may be one or three or more.

The housing 2 is formed of a metal or a conductive resin, and holds the substrate 1 and a part of the sealing member 3 inside. When the USB memory device is connected to the external device, one end of the housing 2 is inserted into a USB port of the external device, which allows the operating terminals 6 to be electrically connected with the external device.

The sealing member 3 is formed, for example, of an insulating resin. The sealing member 3 fixes the substrate 1 into the housing 2 by inserting a part of the sealing member 3 into the housing 2.

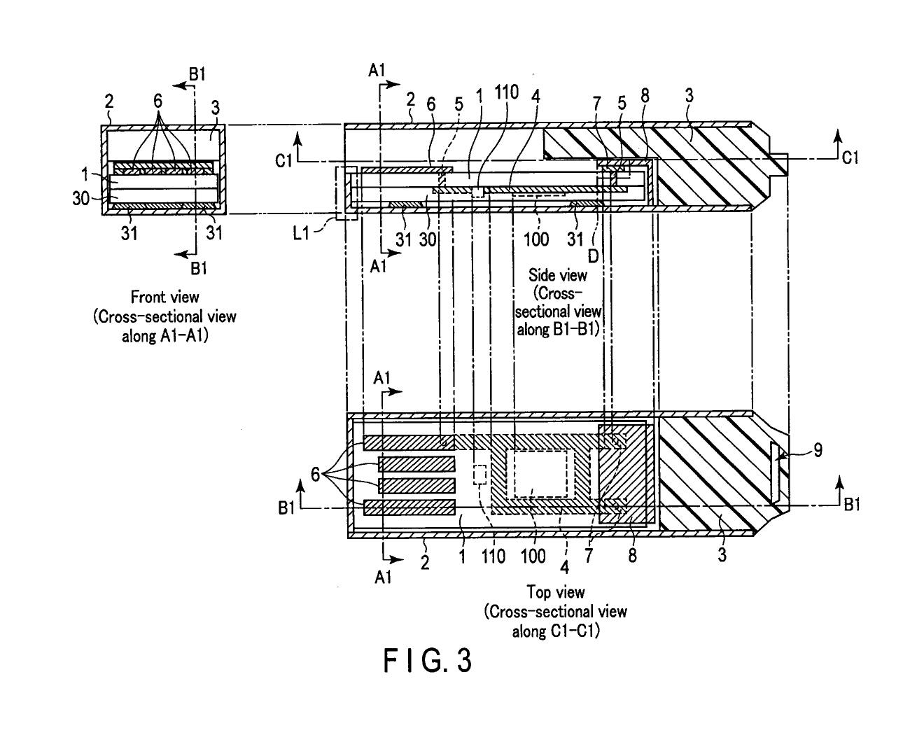

The USB memory device configuration will be described in further detail. FIG. 3 illustrates cross-sectional views of the USB memory device, taken along line A1-A1 (hereinafter referred to as a front view), line B1-B1 (hereinafter referred to as a side view), and line C1-C1 (hereinafter referred to as a top view). In the following description, the left side of FIG. 3 in the direction along line C1-C1 will be defined as the front side of the USB memory device (the side connected to the external device), and the right side of FIG. 3 in the direction along line C1-C1 will be defined as the rear side of the USB memory device. In the drawings, the substrate 1, housing 2, and sealing member 3 are not connected to each other for clarification of their contours; however, they may be contacted to each other.

As shown in the side view and the top view of FIG. 3, the operating terminals 6 and reference potential terminals 7 are provided on the top surface of the substrate 1. The terminals 6 and 7 may be provided such that the entire terminals are embedded in the substrate 1, and the surfaces thereof are exposed. In this case, the upper surface of the terminals 6 and 7 are flush with the upper surface of the substrate 1. Alternatively, the terminals 6 and 7 may be provided such that a part including the bottom surface thereof is embedded in the substrate 1, and the upper surface is exposed. In this case, the upper surface of the terminals 6 and 7 protrudes from the upper surface of the substrate 1.

A semiconductor memory chip 100 and a semiconductor control chip 110 described above are provided on the bottom surface of the substrate 1. The substrate 1 also includes a reference potential wiring 4, a semiconductor element (a passive element such as a resistance or a capacitor and/or an active element such as a transistor) (not shown in the drawings), and a metal wiring (not shown in the drawings) to connect the semiconductor memory chip 100, semiconductor control chip 110, and operating terminals 6. Specifically, the metal wiring connects a terminal receiving a source voltage among the operating terminals 6, the semiconductor memory chip 100, and the semiconductor control chip 110. In addition, the metal wiring connects a terminal transmitting and receiving a control signal or data among the operating terminals 6 and the semiconductor control chip 110. The semiconductor element, reference potential wiring 4, metal wiring, semiconductor memory chip 100, and semiconductor control chip 110 are covered with the sealing resin 30 for protection. The metal wiring may be a multi-layer wiring in that a part thereof is provided on the upper surface or the inside of the substrate 1.

The reference potential wiring 4 is provided to enclose the semiconductor memory chip 100. The reference potential wiring 4 is connected to the reference potential terminals 7 and the operating terminals 6 receiving the reference potential from the external device through a contact 5 formed inside of the substrate 1. The reference potential wiring 4 may be provided on the upper surface of the substrate 1, or inside of the substrate 1 as a multi-layer wiring. When the reference potential wiring 4 is provided on the upper surface and bottom surface of the substrate, the reference potential wiring 4 may be partially or entirely embedded in the substrate 1. The reference potential wiring 4 may be formed to enclose the semiconductor memory chip 100 and the semiconductor control chip 110, and the shape or arrangement thereof is not limited.

As shown in the front view and the side view, the housing 2 includes a pedestal 31 on the bottom surface. The pedestal 31 may be formed by processing a part of the housing 2, or provided on the housing as an independent part. The substrate 1 is placed on the pedestal 31, and the back side of the substrate 1 is in contact with the pedestal 31.

As shown in the side view and the top view, the housing 2 includes a connecting part 8 on the bottom surface, the connecting part 8 connecting the housing 2 with the reference potential terminals 7 of the substrate 1. The connecting part 8 may be formed by processing a part of the housing 2 to form a convex part, or provided on the housing 2 as an independent part. In either case, the connecting part 8 has electric conductivity. A part of the connecting part 8 is in contact with the reference potential terminals 7 of the substrate 1. By this structure, the substrate 1 and the housing 2 are electrically connected to each other. Accordingly, when the USB memory device is connected to the external device, the potential of the housing 2 becomes the same as the reference potential applied from the external device.

As shown in the side view, the bottom surface of the housing 2 has an L-shaped area L1, which is obtained by bending the front end portion of the housing 2 inwards. The front and rear portions of the substrate 1 in the direction along line C1-C1 are fixed between the area L1 and the connecting part 8 so that a side surface of the substrate 1 is in contact with the area L1, and another side surface is in contact with the connecting part 8.

The sealing member 3 is inserted from the rear portion of the housing 2 to be in contact with the connecting part 8. The top and bottom portions of the substrate 1 are fixed between the pedestal 31 and the sealing member 3 through the connecting part 8 formed in the housing 2.

As shown in the top view in FIG. 3, a strap hole 9 through which a strap is attached is formed in the sealing member 3.

In the present embodiment, the housing 2 has four pedestals 31; however, the number of pedestals 31 is not limited to four, and the pedestal 31 may be omitted. In other words, the entire back surface of the substrate 1 may come in contact with the housing 2. Furthermore, in the present embodiment, the L-shaped portion L1 is formed on the front end portion of the bottom surface of the housing 2. However, the shape of the portion L1 is not limited to an L-shape as long as the substrate 1 is fixed and is prevented from falling out to the front.

The strap hole 9 formed in the sealing member 3 may be omitted.

### 1.2 Advantageous Effects of Present Embodiment

The configuration according to the present embodiment enables noise reduction while constraining the area (physical size) of the reference potential wiring 4 used to counter noise in the substrate 1. In the following, the advantageous effects of the present embodiment will be described.

There are various countermeasures for the USB memory device to reduce noise such as electromagnetic interference (EMI) conveyed and radiated from the main body of the device. One of the methods is to arrange a reference potential wiring on the substrate on which a memory chip is implemented. With this method, radiation of noise is suppressed by enclosing the outer peripheral of various circuits provided on the substrate with the reference potential wiring, or by providing a wiring layer which is to be a reference potential in the stacked wiring layers formed on the substrate, for example. However, the above method increases the number of wirings in the reference potential wiring, and accordingly increases the area of the substrate and/or the number of substrate layers.

In contrast, the present embodiment provides the reference potential terminal 7 on the substrate 1. By means of the reference potential terminal 7 and connecting part 8, the reference potential wiring 4 provided on the substrate 1 is connected to the housing 2. Accordingly, when the USB memory device is connected to an external device, the potential of the housing 2 becomes the same as the reference potential applied from the external device.

That is, according to the present embodiment, the housing 2 realizes a function the same as that of the reference potential wiring 4 provided on the substrate 1 for countering noise. Accordingly, the area of the reference potential wiring 4 required on the substrate 1 for countering noise can be reduced. In addition, the substrate 1 can be downsized, and the number of wiring layers (substrate layers) can be reduced. Due to the reduction of the area of the reference potential wiring 4, more semiconductor elements or signal wirings can be implemented on the substrate 1, thereby highly integrating the circuit.

Furthermore, according to the present embodiment, the substrate 1 can be covered with the housing 2 having the same potential as the reference potential. As a result, the noise that may be radiated from the substrate 1 to the outside of the USB memory device can be reduced due to shielding effects of the housing 2.

### 2. Second Embodiment

A USB memory device according to the second embodiment will be described. The present embodiment relates to a configuration of the connecting part 8 of the housing 2 in the first embodiment. In the present embodiment, four examples are specifically shown. In the following, only those items different from the first embodiment will be explained.

### 2.1 First Example

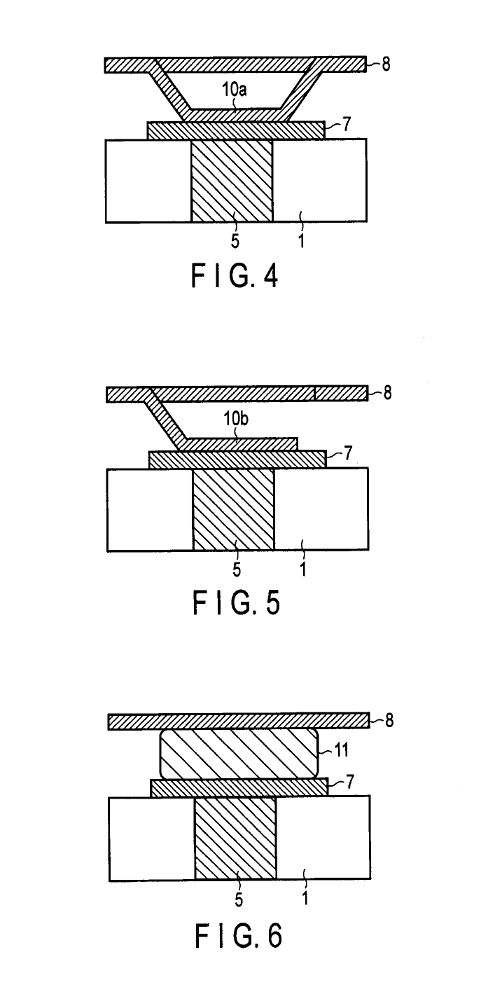

First of all, a configuration of the connecting part 8 in the first example of the present embodiment will be explained. FIG. 4 is an enlarged cross-sectional view of the region D in the side view of FIG. 3, and shows the connected portion between the reference potential terminal 7 and the connecting part 8 according to this example. As shown in FIG. 4, the connecting part 8 has a trapezoidal convex part 10a formed by molding, and the convex part 10a is in contact with the reference potential terminal 7.

In this example, the convex part 10a is a trapezoidal shape viewed from the side; however, may be a polygonal shape such as a rectangle or a triangle, an arc-shape, or a dome-shape.

### 2.2 Second Example

Next, a configuration of the connecting part 8 in the second example of the present embodiment will be explained. In this example, the connecting part 8 has a spring structure formed by cutting a part of the convex part in the first example. FIG. 5 is an enlarged view of the connected portion between the reference potential terminal 7 and the connecting part 8 according to this example. As shown in FIG. 5, the connecting part 8 has a spring structure 10b, one side of which is opened by cutting processing, and the spring structure 10b is in contact with the reference potential terminal 7. The spring structure in this example has an elastic characteristic. For example, the spring structure is deformed when being in contact with the reference potential terminal 7, and recovered to the original shape when not being in contact with the reference potential terminal 7.

In this example, the spring structure 10b is formed of two sides viewed from the side; however, the spring structure 10b may have three sides or more, or have an arc-shape.

### 2.3 Third Example

Next, a configuration of the connecting part 8 in the third example of the present embodiment will be explained. In this example, a conductor is provided on the upper surface of the reference potential terminal 7. In the following, only the items different from the first and second examples will be explained. FIG. 6 is an enlarged view of the connected portion between the reference potential terminal 7 and the connecting part 8 according to this example. As shown in FIG. 6, a conductor 11 is provided on the upper surface of the reference potential terminal 7 in the configuration explained in the first embodiment, and the conductor 11 is in contact with the connecting part 8. That is, the connecting part 8 and the reference potential terminals 7 are electrically connected to each other through the conductor 11. The conductor 11 is formed of a metal or a conductive resin, and is applied or mounted on the upper surface of the reference potential terminal 7.

In FIG. 6, the conductor 11 has a rectangular cross-sectional structure. However, the cross-sectional structure may be a convex shape as shown in FIG. 4, a spring structure as shown in FIG. 5, or a tubular shape having a cavity inside thereof. The conductor 11 may be formed by bunching or folding a sheet conductor, and the shape thereof is not limited.

### 2.4 Fourth Example

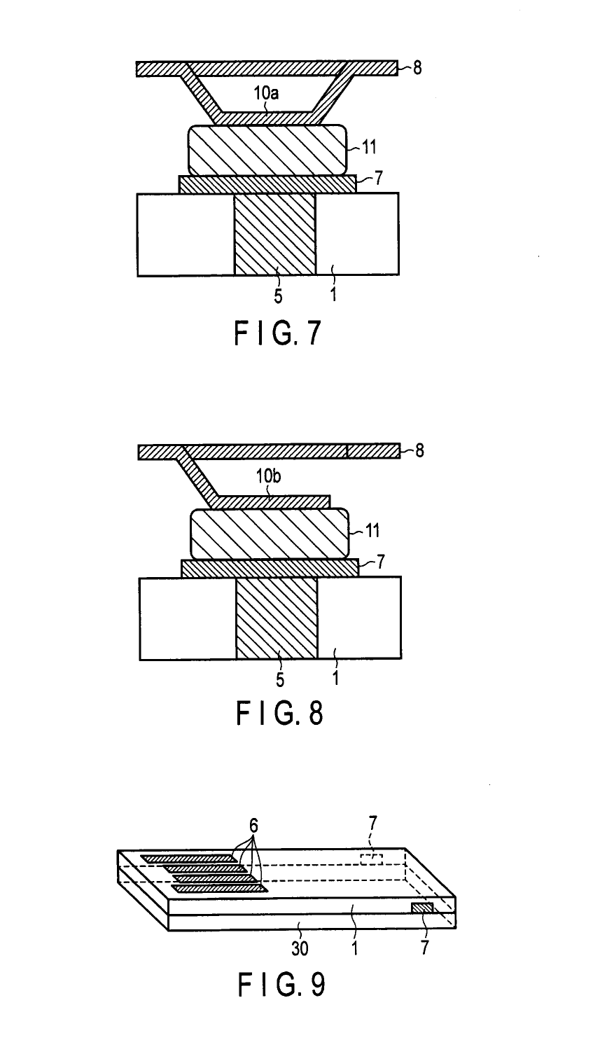

Next, a configuration of the connecting part 8 in the fourth example of the present embodiment will be explained. In this example, the conductor 11 shown in the third example is combined with the trapezoidal convex part 10a shown in the first example, or the spring structure 10b shown in the second example. FIGS. 7 and 8 each illustrate an enlarged view of the connected portion between the reference potential terminal 7 and the connecting part 8 according to this example.

As shown in FIG. 7, the convex part 10a formed in the connecting part 8 as shown in the first example may be in contact with the conductor 11 fixed on the upper surface of the reference potential terminal 7. In addition, as shown in FIG. 8, the spring structure 10b formed in the connecting part 8 as shown in the second example may be in contact with the conductor 11 fixed on the upper surface of the reference potential terminal 7.

### 2.5 Advantageous Effects of Present Embodiment

The configurations explained in the present embodiment can be applied to the connecting part 8 explained in the first embodiment. By the application, the reliability of the electrical connection between the substrate 1 and the housing 2 can be improved.

For example, if the thickness of the substrate 1 or the height of the connecting part 8 varies due to variation in manufacturing, a connection failure between the reference potential terminal 7 and the connecting part 8 may occur. On the other hand, according to the present embodiment, even if the size varies, the connecting part 8 or the conductor 11 is deformed to successfully connect the reference potential terminal 7 and the connecting part 8 electrically. In the example shown in FIG. 6, the conductor 11 may not have to be deformed. In other words, even if the connecting part 8 is processed to have an angle different from the designed angle, the connecting part 8 can be in contact with any parts of the conductor 11. Of course it goes without saying that elastic characteristics of the conductor 11 can accomplish more desirable effects.

### 3. Third Embodiment

A USB memory device according to the third embodiment will be described. In the present embodiment, the reference potential terminals 7 explained in the first and second embodiments are formed on the side surface of the substrate 1. In the following, only the items different from the first and second embodiments will be explained.

### 3.1 Configuration of USB Memory Device

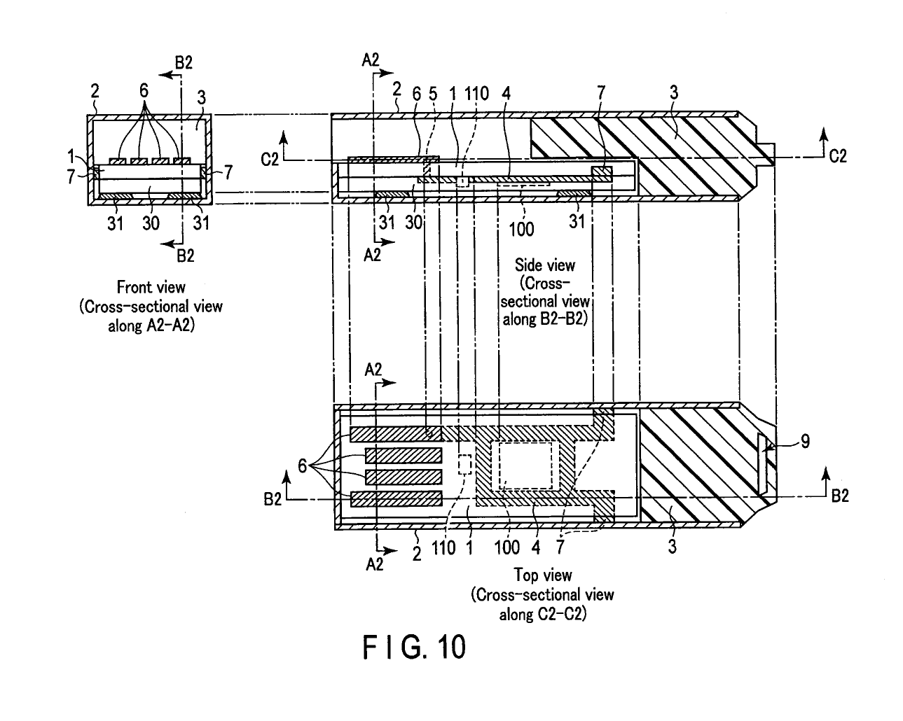

FIG. 9 is a perspective view of the substrate according to the present embodiment, and FIG. 10 is a cross-sectional view of the USB memory device according to the present embodiment. As shown in FIGS. 9 and 10, the substrate 1 has the reference potential terminal 7 on each side surface. The reference potential terminal 7 is in direct contact with the side surface of the housing 2, and is electrically connected to the housing 2. In this embodiment, the reference potential terminals 7 are in direct contact with the housing 2, and accordingly, the connecting part 8 is omitted.

### 3.2 Advantageous Effects of Present Embodiment

The configuration according to the present embodiment realizes the same advantageous effects as the first embodiment.

In the present embodiment, due to the omission of the connecting part 8, the processing of the connecting part 8 is unnecessary, thereby reducing the manufacturing steps of the housing 2. This also reduces manufacturing costs.

The configuration explained in the second embodiment can be applied to the connected portion between the housing 2 and the reference potential terminal 7 of the present embodiment. In other words, the convex part 10a or the spring structure 10b formed to the connecting part 8 in the second embodiment may be formed on the side surface of the housing 2 with which the reference potential terminal 7 is in contact. This configuration realizes the same advantageous effects as the second embodiment.

### 4. Fourth Embodiment

A USB memory device according to the fourth embodiment will be described. In the present embodiment, a concave part with which the reference potential terminal 7 is in contact is formed in the housing 2 explained in the first to third embodiments. The end portion of the sealing member 3 is inserted in the concave part. In the following, only the items different from the first to third embodiments will be explained.

### 4.1 First Example

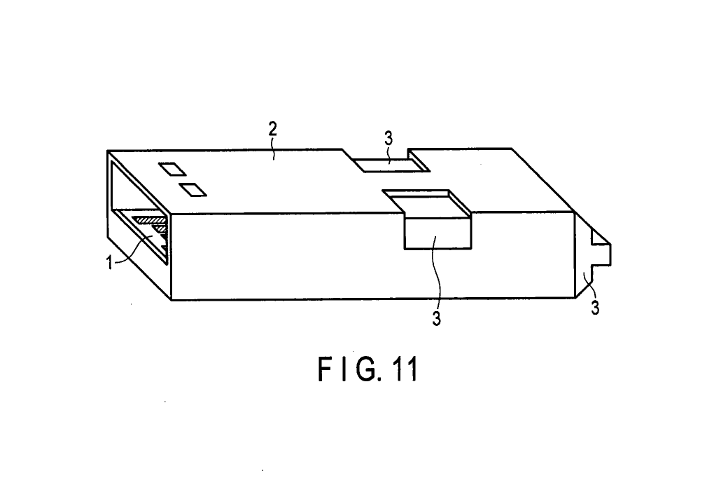

A USB memory device according to the first embodiment will be described. FIGS. 11 to 13 respectively illustrate a perspective view, an exploded view, and a cross-sectional view of the USB memory device according to the present example.

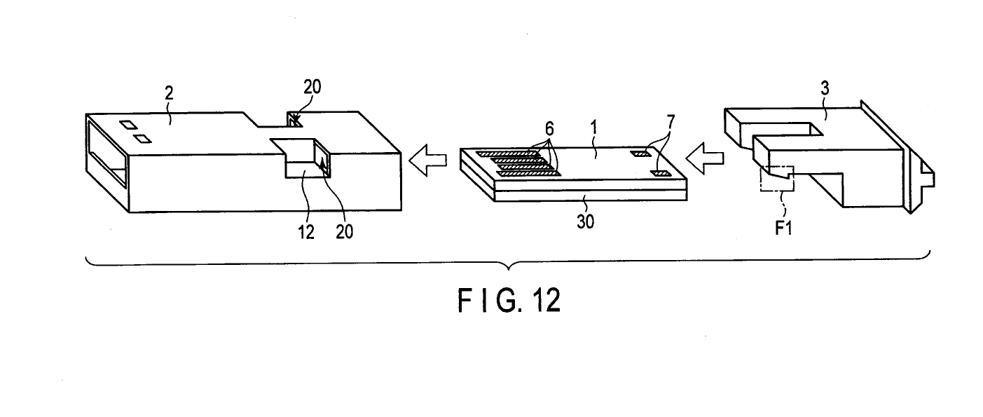

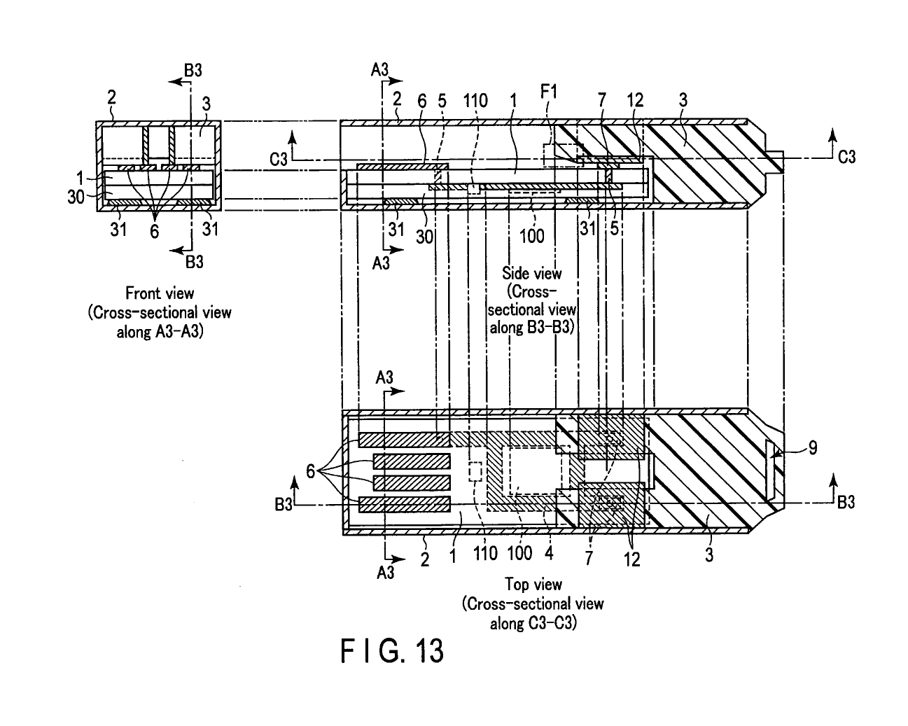

As shown in the drawings, the housing 2 has concave parts that function as connecting parts 12. The connecting parts 12 form openings 20 at the front end and rear end (see FIG. 12). As shown in the side view of FIG. 13, the connecting part 12 is in contact with the reference potential terminal 7 of the substrate 1, thereby electrically connecting the substrate 1 to the housing 2.

The end portion of the sealing member 3 that is to be inserted into the housing 2 is divided into two parts. The bottom surfaces of the divided parts have hooking parts F1. As shown in the side view and the top view of FIG. 13, the end portions of the sealing member 3 are inserted through the openings 20 of the connecting parts 12, and hooked on the connecting parts 12 by the hooking parts F1. By this structure, the sealing member 3 does not easily come out from the housing 2.

The end portions of the sealing member 3 are engaged with the housing 2 through the openings 20, and the sealing member 3 is exposed from the connecting parts 12 of the housing 2 (see FIG. 11).

### 4.2 Second Example

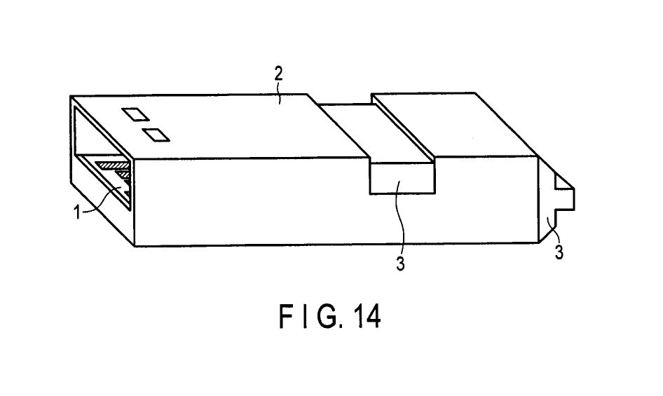

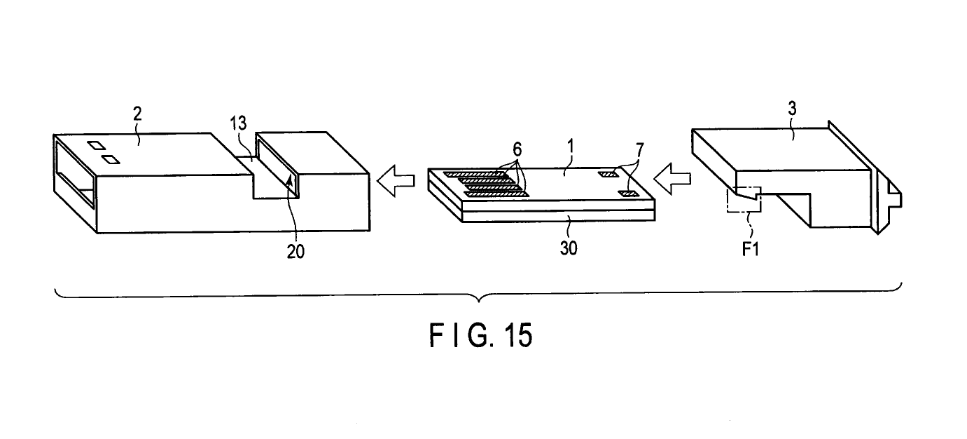

A USB memory device according to the second embodiment will be described. FIGS. 14 and 15 respectively illustrate a perspective view and an exploded view of the USB memory device according to the embodiment.

As shown in the drawings, the two concave parts explained in the first example are connected as a concave part which functions as the connecting part 12. In this example, the housing 2 has a connecting part 13, which is a concave part as viewed from the side. The sealing member 3 is formed to fit the shape of the connecting part 12. Specifically, the sealing member 3 is formed by adding the hooking part F1 at the end portion of the sealing member 3 shown in FIG. 2.

### 4.3 Advantageous Effects of Present Embodiment

The configuration according to the present embodiment realizes the same advantageous effects as the first embodiment.

In addition, in the configuration according to the present embodiment, the area of the sealing member 3 exposed from the connecting parts 12 or connecting part 13 increases. The exposed area can be used for printing of the capacity annotation or various authentication marks. The annotation or marks can be printed on the surface of the sealing member 3 by ink printing, for example. This reduces the cost for printing in comparison with printing them by laser marking on the surface of housing 2, for example.

According to the present embodiment, the exposed area of the sealing member 3 increases. Thus, if the color of the sealing member 3 is changed from the housing, the color difference in the product is well recognized, thereby increasing the effect of changing the appearance of the product.

The configuration explained in the second embodiment can be applied to the connected portion between the connecting parts 12 or connecting part 13 of the housing 2 and the reference potential terminals 7 of the present embodiment. That is, the convex part 10a or the spring structure 10b formed to the connecting part 8 in the second embodiment may be formed in the connecting parts 12 or connecting part 13. This accomplishes the similar connection to that explained in the second embodiment. This configuration exercises the same advantageous effects as the second embodiment.

In this embodiment, the reference potential terminals 7 are provided on the upper surface of the substrate 1. However, the reference potential terminals 7 may be provided on the side surfaces of the substrate 1, as explained in the third embodiment.

### 5. Fifth Embodiment

A USB memory device according to the fifth embodiment will be described. In the present embodiment, a part of the side surfaces of the housing 2 explained in the first to fourth embodiments is folded toward the inside of the housing 2. In the following, only the items different from the first to fourth embodiments will be explained.

### 5.1 Configuration of USB Memory Device

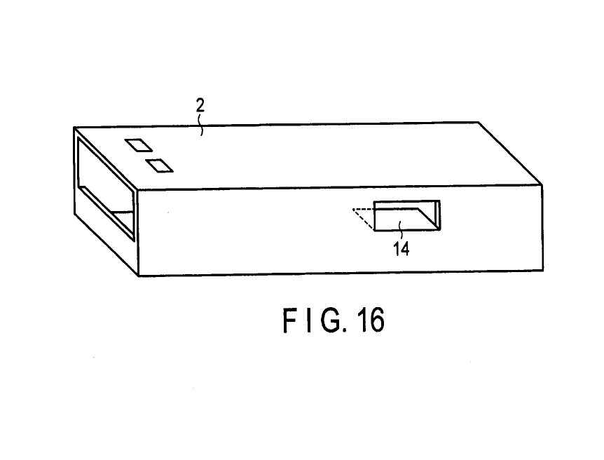

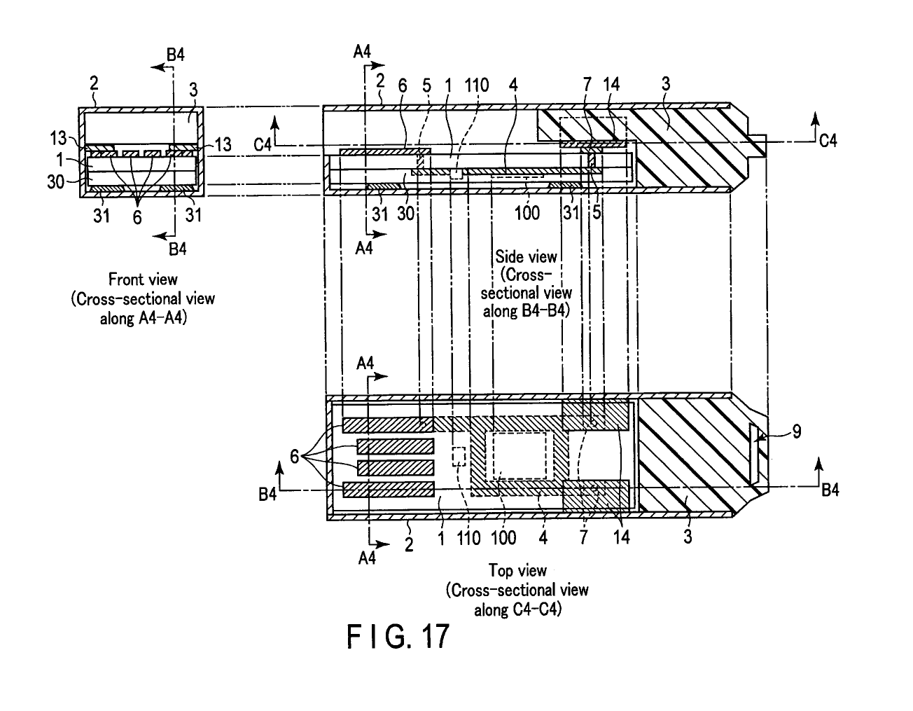

FIGS. 16 and 17 respectively illustrate a perspective view of the housing 2 and a cross-sectional view of the USB memory device according to the embodiment.

As shown in the drawings, a part of both side surfaces of the housing 2 is folded toward inside of the housing 2. The folded parts function as connecting parts 14. The reference potential terminals 7 are in contact with the connecting parts 14. In this embodiment, a connecting part 14 is formed on each side surface of the housing 2. However, the number of the connecting parts 14 may be two or more.

### 5.2 Advantageous Effects of Present Embodiment

The configuration according to the present embodiment realizes the same advantageous effects as the first and fourth embodiments.

The configuration explained in the second embodiment can be applied to the connected portion between the folded parts of the connecting parts 14 of the housing 2 and the reference potential terminals 7 of the present embodiment. That is, the convex part 10a or the spring structure 10b formed to the connecting part 8 in the second embodiment may be formed in the connecting parts 14. This accomplishes the similar connection to that explained in the second embodiment. This configuration exercises the same advantageous effects as the second embodiment.

### 6. Sixth Embodiment

A USB memory device according to the sixth embodiment will be described. In the present embodiment, the sealing member 3 explained in the first to fifth embodiments is omitted. In the following, only the items different from the first to fifth embodiments will be explained.

### 6.1 Configuration of USB Memory Device

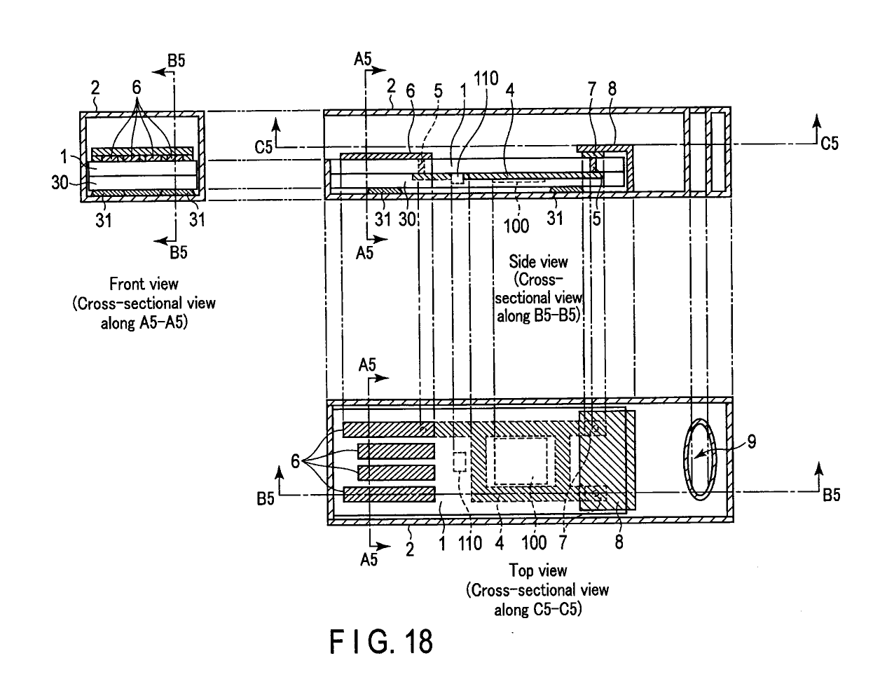

FIG. 18 is a cross-sectional view of the USB memory device according to the present embodiment. As shown in the side view of FIG. 18, the connecting part 8 provided inside of the housing is in contact with the reference potential terminal 7 on the substrate 1, the same as in the first embodiment, thereby electrically connecting the substrate 1 to the housing 2. The substrate 1 has the same configuration as that in the first embodiment.

The rear surface of the housing 2 is sealed. Accordingly, the sealing member 3 is omitted in this embodiment. The housing 2 forms the strap hole 9 through which a strap is attached.

### 6.2 Advantageous Effects of Present Embodiment

The configuration according to the present embodiment realizes the same advantageous effects as the first embodiment.

In the present embodiment, due to the omission of the connecting part 3, the material costs and the manufacturing steps can be reduced. Accordingly, the manufacturing costs are also reduced.

The configuration explained in the second and third embodiments can be applied to the present embodiment. In such a case, the advantageous effects explained in each embodiment can be realized.

The strap hole 9 formed in the housing 2 may be omitted.

### 7. Seventh Embodiment

A USB memory device according to the seventh embodiment will be described. In the present embodiment, a conductor that covers the reference potential terminal 7 is attached to the substrate 1 explained in the first to sixth embodiments. In the following, only the items different from the first to sixth embodiments will be explained.

### 7.1 Configuration of USB Memory Device

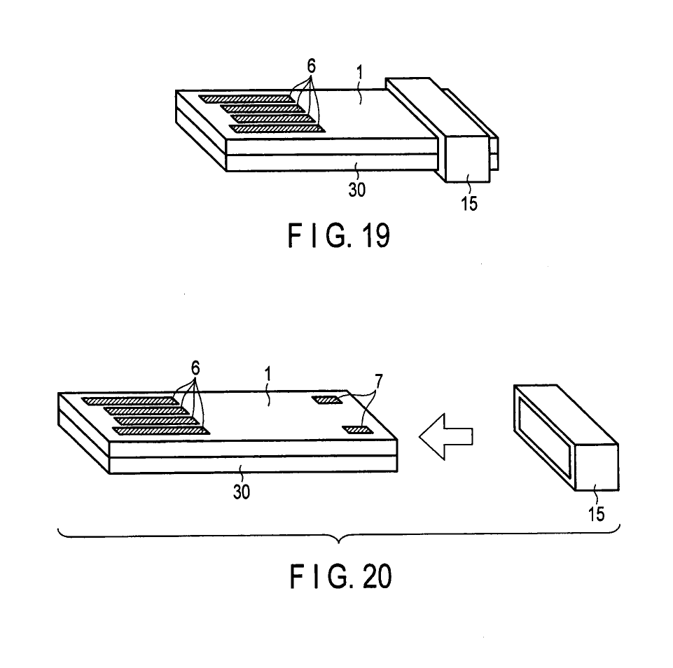

FIGS. 19 to 21 respectively illustrate a perspective view of the substrate 1, an exploded view of the substrate 1, and a cross-sectional view of the USB memory device according to the embodiment.

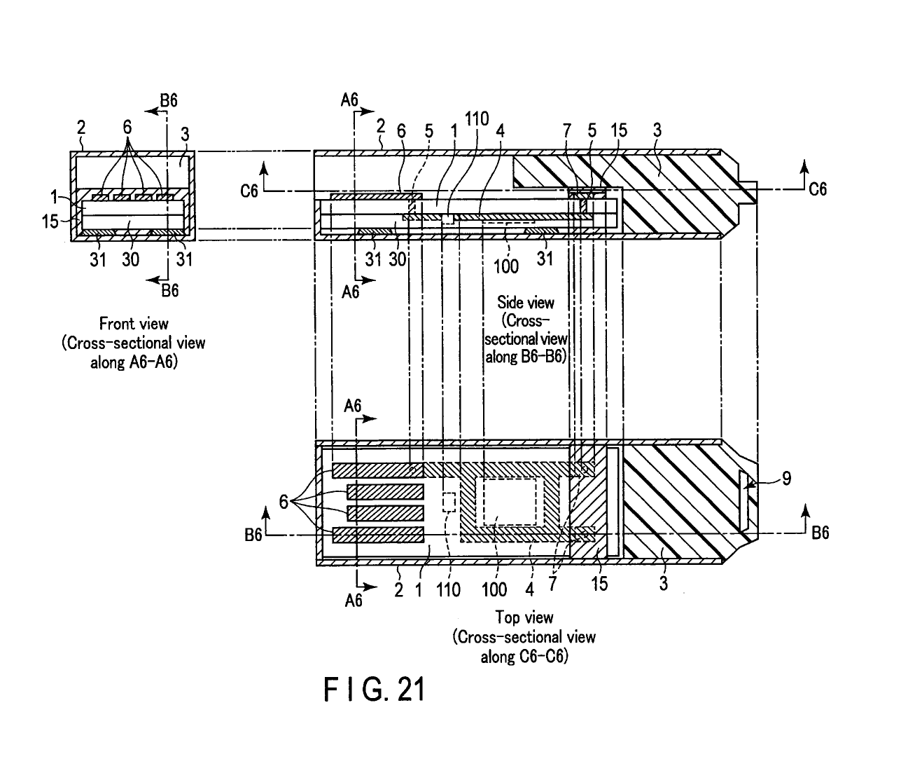

As shown in FIGS. 19 to 21, a conductor 15 which is, for example, a hollow rectangular parallelepiped, is provided to the substrate 1 to cover the reference potential terminals 7. The reference potential terminals 7 are in contact with the inner surface of the conductor 15. The conductor 15 is formed of a metal or a conductive resin, and is electrically connected with the reference potential terminals 7 on the substrate. As shown in the side view and the top view of FIG. 21, the conductor 15 is in contact with the side surface and/or the bottom surface of the housing 2, thereby electrically connecting the substrate 1 to the housing 2.

### 7.2 Advantageous Effects of Present Embodiment

The configuration according to the present embodiment realizes the same advantageous effects as the first embodiment.

According to the present embodiment, since the conductor 15 is in contact with the side surface and/or the bottom surface of the housing 2, the connecting area increases, thereby reducing connection failure due to variations in size of the substrate 1 and the housing 2.

In addition, the configuration explained in the second to fifth embodiments can be applied to the present embodiment. In such a case, the advantageous effects explained in each embodiment can be realized.

In this embodiment, the reference potential terminals 7 are provided on the upper surface of the substrate 1. However, the reference potential terminals 7 may be provided on the side surfaces of the substrate 1.

### 8. Eighth Embodiment

A USB memory device according to the eighth embodiment will be described. In the present embodiment, the sealing member 3, explained in the first to fifth and seventh embodiments, is formed of a conductive material. In the following, only the items different from the first to fifth and seventh embodiments will be explained.

### 8.1 Configuration of USB Memory Device

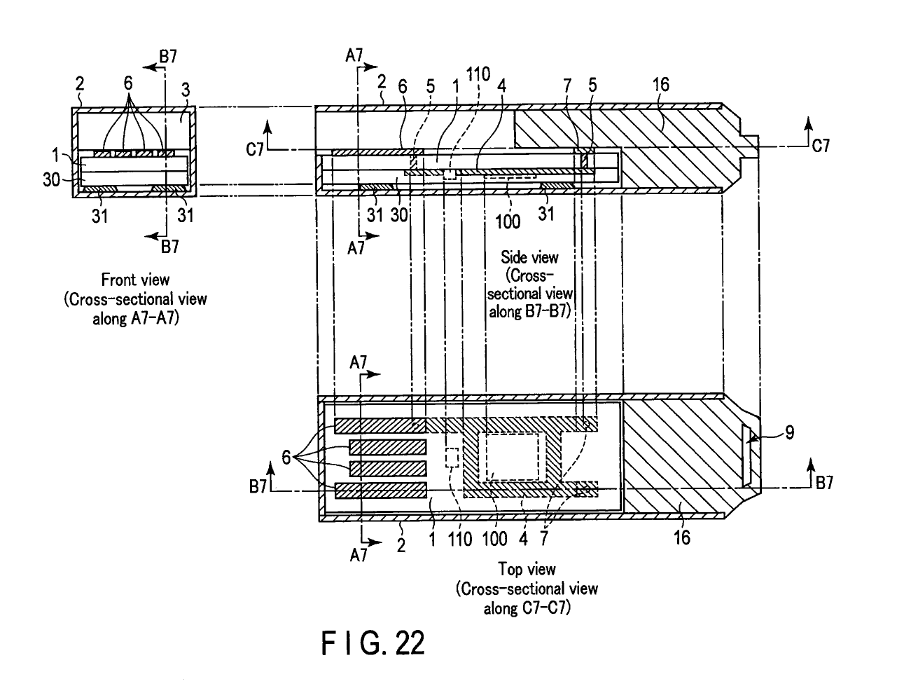

FIG. 22 is a cross-sectional view of the USB memory device according to the present embodiment. As shown in FIG. 22, the sealing member 16 is formed of a metal or a conductive resin, and is electrically connected with the housing 2 and the reference potential terminals 7 on the substrate 1. Unlike the first embodiment, the reference potential terminals 7 are electrically connected to the sealing member 16, and accordingly, the connecting part 8 is omitted from the housing 2. The substrate 1 has the same configuration as that in the first embodiment.

### 8.2 Advantageous Effects of Present Embodiment

The configuration according to the present embodiment realizes the same advantageous effects as the first embodiment.

In the present embodiment, due to the omission of the connecting part 8, the processing of the connecting part 8 is unnecessary, thereby reducing the manufacturing steps of the housing 2. This also reduces manufacturing costs.

In addition, according to the present embodiment, the potential of the sealing member 16 is the same as the reference potential. Accordingly, the shielding effect to the substrate 1 is increased, and noise to be radiated is also reduced.

The configuration explained in the second embodiment can be applied to the connected portion between the sealing member 16 and the reference potential terminal 7 of the present embodiment. That is, the convex part 10a or the spring structure 10b formed to the connecting part 8 in the second embodiment may be formed at the portion where the sealing member 16 is in contact with the reference potential terminal 7. This accomplishes the similar connection to that explained in the second embodiment. This configuration exercises the same advantageous effects as the second embodiment.

The configuration explained in the second embodiment can be applied to the connected portion between the housing 2 and the sealing member 16 of the present embodiment. In this case, the connection similar to that explained in the second embodiment is accomplished by forming the convex part 10a or the spring structure 10b to the housing 2 or the sealing member 16. This configuration exercises the same advantageous effects as the second embodiment.

In addition, the configuration explained in the fourth, fifth, and seventh embodiments can be applied to the present embodiment. In such a case, the advantageous effects explained in each embodiment can be realized.

### 9. Modified Example, Etc.

The USB memory device according to the aforementioned embodiments includes the substrate (1 in FIG. 2) and the housing (2 in FIG. 2). The substrate includes a semiconductor chip (100 in FIG. 3) capable of storing data, a plurality of operating terminals (6 in FIG. 3) electrically connectable to an external device, a reference potential terminal (7 in FIG. 3), and a reference potential wiring (4 in FIG. 3). The housing holds the substrate inside, is electrically connected to the reference potential terminal (FIG. 3), and has electric conductivity. One of the operating terminals is applied a reference potential from an external device. The reference potential wiring electrically connects the one of operating terminals with the reference potential terminal.

According to the aforementioned embodiments, a USB memory device that is capable of constraining an increase in wiring area and reducing noise can be provided.

The above embodiment is only an example. Therefore, each embodiment can be variously modified. Furthermore, each of the embodiments can be combined to the extent possible. For example, in the configuration explained in the first embodiment, the sealing member 3 may be replaced with the conductive-type sealing member 16 explained in the eighth embodiment, and the convex part 10a or the spring structure 10b explained in the second embodiment may be formed in the connecting part 8 and the sealing member 16.

In the aforementioned embodiments, the reference potential terminals 7 are formed on the upper surface or the side surfaces of the substrate 1; however, they may be formed on the bottom surface of the substrate 1. The reference potential terminals 7 may be formed on multiple places of the upper surface, side surface and bottom surface of the substrate 1. For example, the reference potential terminals 7 may be formed on the upper surface and the side surface, or on the upper surface, side surface, and the bottom surface.

Furthermore, in the first to fifth, seventh, and eighth embodiments, a part of the housing 2 may be cut off to expose the sealing member 3 or 16. The exposed area of the sealing member 3 or 16 may be increased at the rear portion of the USB memory device. A mark or character may be printed on the exposed area of the sealing member 3 or 16.

While certain embodiments have been described, these embodiments have been presented by way of example only, and are not intended to limit the scope of the claims. Indeed, the novel methods and systems described herein may be embodied in a variety of other forms; furthermore, various omissions, substitutions and changes in the form of the methods and systems described herein may be made without departing from the spirit of the embodiments. The accompanying claims and their equivalents are intended to cover such forms or modifications as would fall within the scope and spirit of the embodiments.

What is claimed is:

1. A USB memory device comprising:
a substrate including a semiconductor chip capable of storing data, a plurality of operating terminals electrically connectable to an external device, a reference potential terminal, and a reference potential wiring; and
a housing holding the substrate inside, being electrically connected to the reference potential terminal, and having electric conductivity,
wherein one of the operating terminals is applied a reference potential from the external device, and
wherein the reference potential wiring electrically connects the one of operating terminals with the reference potential terminal.

2. The device according to claim 1, wherein the housing includes a connecting part in contact with the reference potential terminal.

3. The device according to claim 1, wherein the housing has a convex part at a position where the housing is in contact with the reference potential terminal.

4. The device according to claim 1, wherein the housing has a spring structure at a position where the housing is in contact with the reference potential terminal.

5. The device according to claim 1, further comprising a conductor on a surface of the reference potential terminal, the conductor being in contact with the housing.

6. The device according to claim 1, wherein the housing is formed of a metal or a conductive resin.

7. The device according to claim 1, wherein the reference potential terminal is on an upper surface of the substrate.

8. The device according to claim 1, wherein the reference potential terminal is on a side surface of the substrate.

9. The device according to claim 1, further comprising a sealing member fixing the substrate inside the housing.

10. The device according to claim 1, wherein the housing includes a portion folded toward inside, the folded portion being in contact with the reference potential terminal.

11. The device according to claim 1, wherein the substrate further includes a semiconductor element, and a resin covering the semiconductor chip and the semiconductor element.

12. The device according to claim 1, wherein the operating terminals each includes:
a first terminal capable of receiving a source potential from the external device;
a second terminal which transmits and receives a signal to and from the external device; and
a third terminal capable of receiving a reference potential from the external device,
wherein the substrate further includes:
a control chip controlling the semiconductor chip; and
a wiring through which the source potential is transferred to the semiconductor chip and the control chip, and the signal is transferred to the control chip, and
wherein the reference potential wiring transfers the received reference potential to the reference potential terminal.

13. The device according to claim 1, wherein the reference potential wiring encloses an outer peripheral of the semiconductor chip.

14. The device according to claim 1, wherein the reference potential is a ground potential.

15. The device according to claim 5, wherein the conductor is formed of a metal or a conductive resin.

16. The device according to claim 9, wherein the housing has a concave part through which a part of the sealing member engaged.

17. The device according to claim 9, wherein the sealing member is formed of a conductive resin, and is electrically connected to the reference potential terminal.

18. The device according to claim 17, wherein the sealing member has a convex part at a position where the sealing member is in contact with the reference potential terminal.

19. The device according to claim 17, wherein the sealing member has a spring structure at a position where the sealing member is in contact with the reference potential terminal.

20. A USB memory device comprising:
a substrate including a semiconductor chip capable of storing data, a terminal electrically connectable to an external device, a reference potential terminal, a reference potential wiring electrically connecting the terminal and the reference potential terminal; and
a housing holding the substrate, and being electrically connected to the reference potential terminal.
